(19) United States
(12) Patent Application Publication
(10) Pub. No.: US 2012/0025362 A1
(43) Pub. Date: Feb. 2, 2012

(54) Reinforced Wafer-Level Molding to Reduce Warpage

(75) Inventors: Arvind Chandrasekaran, San Diego, CA (US); Shiqun Gu, San Diego, CA (US); Zhongping Bao, San Diego, CA (US)

(73) Assignee: QUALCOMM INCORPORATED, San Diego, CA (US)

(21) Appl. No.: 12/846,910

(22) Filed: Jul. 30, 2010

(51) Int. Cl. H01L 21/50; H01L 21/56; H01L 23/28

(52) U.S. Cl. 257/680; 438/107; 438/126; 257/E21.502; 257/E21.499; 257/E23.116

(57) ABSTRACT

A method for forming an electrical package to reduce warpage. The method includes providing a wafer and coupling a die thereto. A mold compound material is applied to the wafer such that the mold compound material surrounds the die. The method further includes applying a reinforcing material to the mold compound material. The mold compound material is thereby disposed between the wafer and the reinforcing material.

### FIELD OF DISCLOSURE

This disclosure relates generally to electronic packaging, and in particular to a reinforcing material applied to a package for reducing warpage.

### BACKGROUND

In electronic packaging, circuit devices in a chip are being manufactured smaller and lighter, but are required to perform greater functionality. These packages must also include a larger number of input and output connections. The semiconductor devices must also protect the chip from moisture and mechanical damage (e.g., cracking, warpage, etc.). As the chip performs more functions, however, greater power is consumed and more heat is generated. Also, as the size of the chip is reduced, the generated heat is required to dissipate from a smaller surface area. In a silicon chip, for example, it can be difficult to control the silicon surface and junction temperature.

In wafer level packaging, wafer warpage continues to be a concern. This is particularly true with thin dies or wafer stacking and assembly. Warpage can prevent successful assembly of a die-to-wafer stack because of the inability to maintain the coupling of the die and wafer. Also, during temperature cycling, thermal stresses can cause other mechanical defects such as cracking. One solution to the warpage problem is using a window wafer-based die-to-wafer process. The drawback to this solution is that the process can be very long and it is difficult to manufacture these packages at a high volume. Another possible solution is using a low coefficient of thermal expansion mold compound material between the die and wafer. However, there continue to be reliability issues with this type of wafer-level package such that it too cannot be produced at high volumes.

Therefore, it would be desirable to develop an electronic package and method of manufacturing the package which could overcome the warpage and mechanical defects of conventional electronic packages. In addition, it would be desirable for the electronic package to be manufactured at high volumes while also reducing the reliability concerns of conventional packages.

### SUMMARY

For a more complete understanding of the present disclosure, reference is now made to the following detailed description and the accompanying drawings. In an exemplary embodiment, a method for forming an electronic package is provided. The method includes providing a wafer and coupling a die to the wafer. A mold compound material is applied to the wafer such that the mold compound material surrounds the die. The method further includes applying a reinforcing material to the mold compound material. The mold compound material is therefore disposed between the wafer and the reinforcing material. The reinforcing material can be glass and include mechanical properties similar to the wafer.

In one form of the method, the die is coupled to the wafer before applying the mold compound material. The wafer can also be mounted to a carrier and frontside bumping can be applied before mounting the wafer. After the wafer is mounted to the carrier, the wafer is later removed from the wafer. In doing so, the reinforcing material is applied before the wafer is removed from the carrier. The frontside bumping can be applied, however, after the wafer is removed from the carrier.

In another form of the method, a portion of the reinforcing material can be roughened before applying the reinforcing material. The thickness of the reinforcing material can be approximately between the thickness of the wafer and the combined thickness of the wafer, the die, and the mold compound material.

The reinforcing material can be prefabricated and then applied to the mold compound material. In addition, the reinforcing material can be applied to the mold compound material and then cured. The reinforcing material can be cured by using an adhesive material. In a different form of the present embodiment, a piston can be used for applying the reinforcing material to the mold compound material. A vacuum can also be used to apply the reinforcing material to the mold compound material. When coupling the die to the wafer, the die can comprise a plurality of die.

In another embodiment, an electronic package includes a stack of semiconductor die and a mold compound material for supporting the stack. The mold compound material can surround the stack. The package also can include a reinforcing material that has similar mechanical properties to the stack of semiconductor die. The mold compound material is disposed between the stack and the reinforcing material. The reinforcing material can be glass or silicon, and it can be applied non-continuously or as a layer. In addition, at least a portion of the reinforcing material has a roughened surface. The roughened surface can be disposed in contact with the mold compound material. Also, flip chip bumping can be completed on the front side of the stack of semiconductor die.

In a different embodiment, an electronic package assembly includes a stack of semiconductor die, a means for reducing warpage in the assembly, and a means for supporting the stack. The means for reducing has similar mechanical properties as the stack and the means for supporting surrounds the stack. The means for supporting is also disposed between the stack and the means for reducing.

In one form of this embodiment, the means for reducing can be glass or silicon. Also, at least a portion of the means for reducing can have a roughened surface. The roughened surface can be in contact with the means for supporting. In another form, the means for supporting can be an epoxy-based or silicon-based material. In addition, flip chip bumping can be completed on the front side of the stack of semiconductor die. This embodiment of the package can be incorporated into a device selected from a group consisting of a music player, a video player, an entertainment unit, a navigation device, a communications device, a personal digital assistant (PDA), a fixed location data unit, and a computer.

In another exemplary embodiment, a method of fabricating a reinforced electronic package is provided. The method includes providing a stack of semiconductor die and a reinforcing material. A mold compound material is applied to the stack such that the mold compound material surrounds a portion of the stack. The method further includes a step for reducing warpage in the package. The mold compound material can be disposed between the stack and the reinforcing material. In addition, the method includes mounting the stack to a carrier and applying frontside bumping after the stack is removed from the carrier. The stack can be removed from the carrier after the step for reducing warpage. In addition, a portion of the reinforcing material can be roughened.

In the above-described embodiments, a balanced system is achieved which reduces warpage. In at least one of the above-described embodiments, warpage can be reduced by 50-90% based on various glass thicknesses, mold compound material thicknesses, and glass properties. In addition, the above-described embodiments are more reliable and can be manufactured at high volume more easily than conventional packages.

### BRIEF DESCRIPTION OF THE DRAWINGS

FIG. 1 is a flow diagram of a first embodiment for forming an electronic package with improved reliability;

FIG. 2 is a schematic view of a wafer;

FIG. 3 is a schematic view of the wafer of FIG. 1 mounted on a carrier;

FIG. 4 is a schematic view of a plurality of die coupled to the wafer of FIG. 1;

FIG. 5 is a schematic view of a reinforcing material being coupled to a mold compound material and the wafer of FIG. 1;

FIG. 6 is a schematic view of the electronic package after carrier demount;

FIG. 7 is a flow diagram of a second embodiment for forming an electronic package with improved reliability;

FIG. 8 is a schematic view of a wafer;

FIG. 9 is a schematic view of the wafer of FIG. 8 mounted on a carrier;

FIG. 10 is a schematic view of a plurality of die coupled to the wafer of FIG. 8;

FIG. 11 is a schematic view of a reinforcing material being coupled to a mold compound material and the wafer of FIG. 8;

FIG. 12 is a schematic view of the electronic package after carrier demount;

FIG. 13 is a schematic view of the electronic package of FIG. 12 including flip chip bumps; and

FIG. 14 is a block diagram showing an exemplary wireless communication system in which it may be advantageous to use a package having a reinforcing layer.

### DETAILED DESCRIPTION

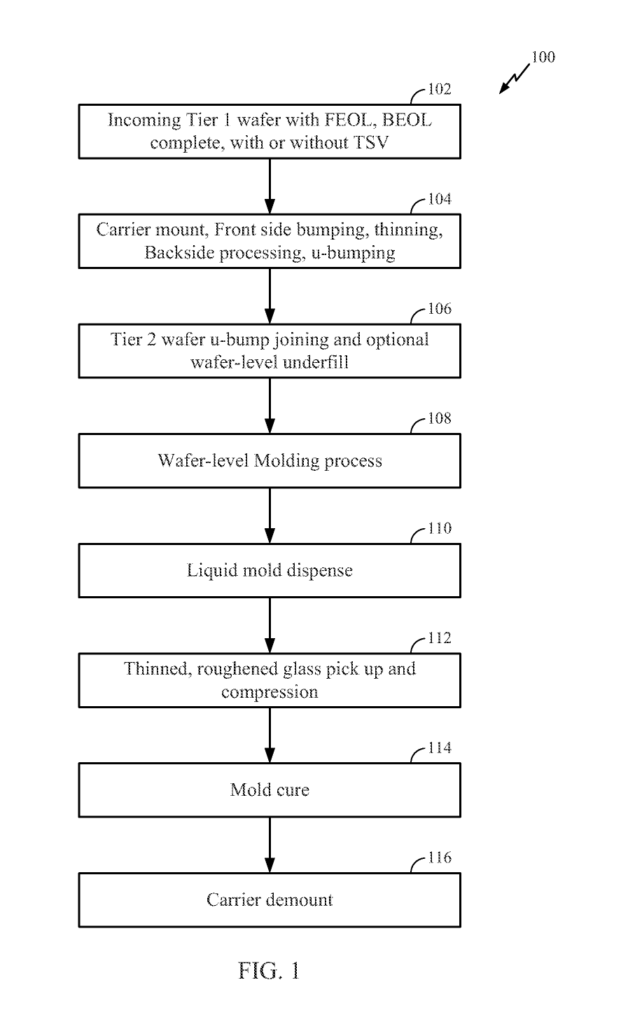

An exemplary embodiment of the present invention is shown in FIGS. 2-6 and an exemplary method for making such an embodiment is shown in FIG. 1. In this embodiment, a method 100 (FIG. 1) is provided for forming an electronic package with improved reliability. The design of the electronic package includes increased stiffness to reduce warpage and other mechanical stresses. In block 102 of the method 100, a wafer 202 is provided. The wafer 202 (FIG. 2) can be formed of silicon, for example, or other known wafer materials. The wafer 202, which can also be referred to as the Tier 1 wafer, can include front-end-of-the-line (FEOL) and back-end-of-the-line (BEOL) processing. Through-silicon vias, for example, can also be fabricated in the wafer 202.

Referring to FIG. 3 and block 104 of method 100, solder bumps 306 can be formed on the frontside of the wafer 202. The solder bumps 306, which can be any conductive material, is used for coupling the package to a substrate, chip, or other device. Once the frontside bumping is achieved, an adhesive material 304 can be applied to the frontside of the wafer between the bumps 306. The wafer 202 can then be mounted to a carrier 302, such as a tape carrier, for further assembly and processing. The carrier 302 can provide sufficient stiffness to the wafer 202 for additional assembly processing. This can be important particularly when the wafer undergoes a thinning process. When a thin die, e.g., a die thickness of approximately 50 μm, is formed from the wafer, the die can bend and/or sustain damage due to material stress from various assembly processes. Thus, the carrier 302 provides improved stiffness and rigidity to the thin die, i.e. wafer 202, during assembly processing.

Other assembly processes can include u-bumping, flip chip bumping, and backside processing. In block 106 of method 100 and FIG. 4, for example, a die 402 is coupled to the wafer 202. An optional underfill layer 308 can be disposed between the die 402 and wafer 202 to enhance the reliability of the package. A plurality of u-bumps 404 couple the die 402 to the wafer 202. The die 402 can be referred to as a Tier 2 die. As shown, there can be a plurality of Tier 2 dies 402 coupled to the wafer 202 through a plurality of u-bumps 404. And, although not shown, additional dies can be stacked to achieve a desired package.

Referring to block 108 of method 100, a wafer-level molding process is performed. A mold compound 502, which can be, for example, an epoxy-based material, is applied to the package such that the plurality of dies 402 is substantially surrounded by the mold compound 502 and the backside of the wafer 202 is substantially covered by the mold compound 502. The mold compound 502 provides rigidity to the package, but it is unable to provide sufficient stiffness required to prevent or significantly reduce warpage. Even applying a thicker layer of mold compound 502 is undesirable because it increases the overall height of the package and can be expensive. Thus, the thickness of the mold compound 502 is applied such that the mold compound 502 surrounds the plurality of dies 402 and covers the backside of the wafer 202.

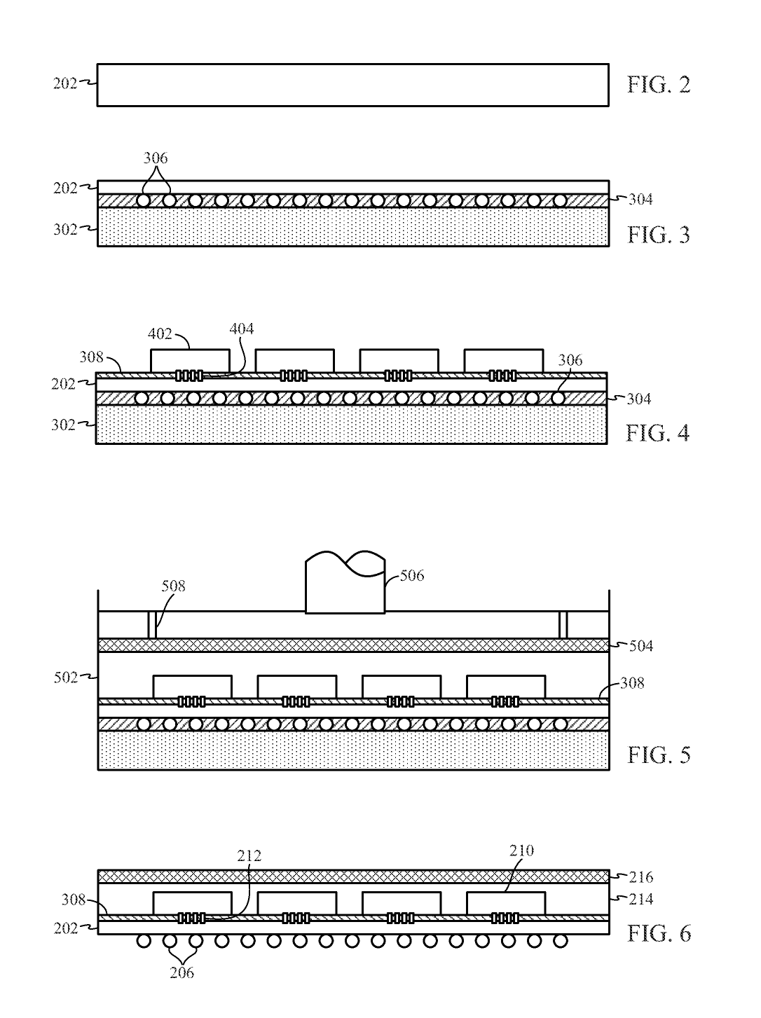

The mold compound 502 can be applied in several ways. In one embodiment, the mold compound 502 can be dispensed onto the backside of the wafer, spun in a circular motion to spread the mold compound 502 evenly, and then compressed. In the embodiment of block 110 and FIG. 5, the mold compound 502 is liquid-based and compressed using a piston 506. Once the mold compound 502 is compressed to a desired thickness, it is cured at a curing temperature. The curing temperature can be between 150-250° C., for example. Depending on the type of mold compound, the curing temperature may vary.

Once the mold compound cures, a reinforcing material 504 can be applied to the mold compound 502. In block 112, a thin reinforcing material 504 is disposed on the backside of the mold compound 502. The reinforcing material 504 can be glass, for example, or any other material that has similar mechanical and thermal properties as the wafer 202. Since glass and silicon have similar properties such as stiffness and coefficient of thermal expansion (CTE), the two materials can advantageously balance or reduce stresses and warpage during assembly and use.

It is desirable for the reinforcing material 504 to have a small thickness so that the overall package height is minimal. The reinforcing layer 504 can be applied as a continuous or non-continuous layer on the mold compound 502. Advantageously, the mold compound 502 can have a thickness between 100-400 μm and the reinforcing material 504 can have a thickness of up to about 400 These thicknesses are non-limiting, however, and different embodiments of an electronic package can include a mold compound 502 and reinforcing material 504 having thicknesses outside of these ranges.

The reinforcing material 504 can be prefabricated or applied to the mold compound and then cured. As described above, the mold compound 504 can be cured before the reinforcing layer 504 is applied. However, in an alternative embodiment, the prefabricated reinforcing material 504 can be used for compressing the mold compound 502. For example, once the mold compound 502 is applied to the backside of the wafer 202, the prefabricated reinforcing material 504 can compress the mold compound 502 to its desired thickness. In this example, once the mold compound 502 is compressed, it cures at the curing temperature in block 114 of method 100.

The prefabricated reinforcing material 504 can be used solely or in combination with the piston 506 for compressing the mold compound. When used in combination, a vacuum can be created through channels 508 (FIG. 5) defined in the piston 506 for coupling the reinforcing material 504 to the piston 506. The combined reinforcing material 504 and piston 506 can apply a uniform amount of pressure to the mold compound 502 to achieve a desired mold compound thickness. In addition, the piston 506 provides support to the thin reinforcing material 504 during the compression process.

Once the mold compound 502 is compressed to the desired thickness, the mold compound 502 couples to the reinforcing material 504 and the vacuum pressure is released. The piston 506 can be removed from the reinforcing material 504 and the assembly is cured in block 114. In block 116 of the method 100 and FIG. 6, the carrier 302 is removed from the wafer 202 and the wafer can be diced. The bumps 306 on the frontside of the wafer 202 can now be coupled to a chip or substrate.

In block 112, the coupling of the mold compound 502 and reinforcing material 504 can be aided or promoted by a surface roughening process. The surface of the reinforcing material 504, for example, can be roughened before coupling the mold compound 502 and reinforcing material 504. There are several roughening processes or techniques that can be used. For example, the roughening process can be achieved by a dry or wet etching process. Plasma bombardment or etching is one form of a dry etching process that can be used.

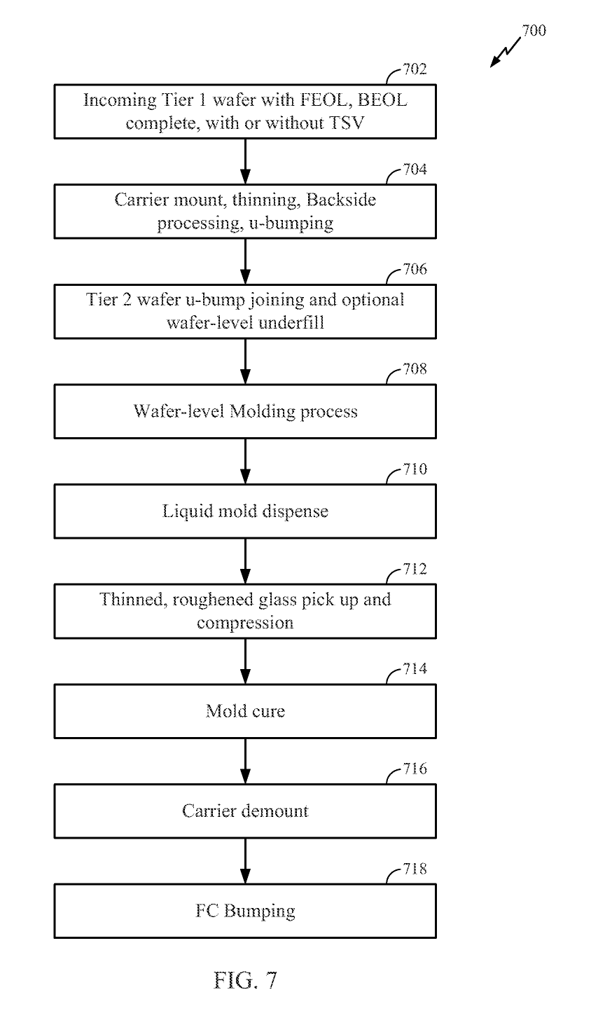

Referring to FIG. 7, another exemplary embodiment of a method 700 is provided for forming an electronic package with improved reliability. Similar to the embodiment of FIG. 1, the method 700 fabricates the electronic package with increased stiffness to reduce warpage and other mechanical stresses. In block 702 of the method 700, a wafer 802 is provided. The wafer 802 (FIG. 8) can be formed of silicon, for example, or other known wafer materials. The wafer 802, or Tier 1 wafer, can include front-end-of-the-line (FEOL) and back-end-of-the-line (BEOL) processing. Similar to the wafer 202 in FIG. 2, through-silicon vias can also be fabricated in the wafer 802.

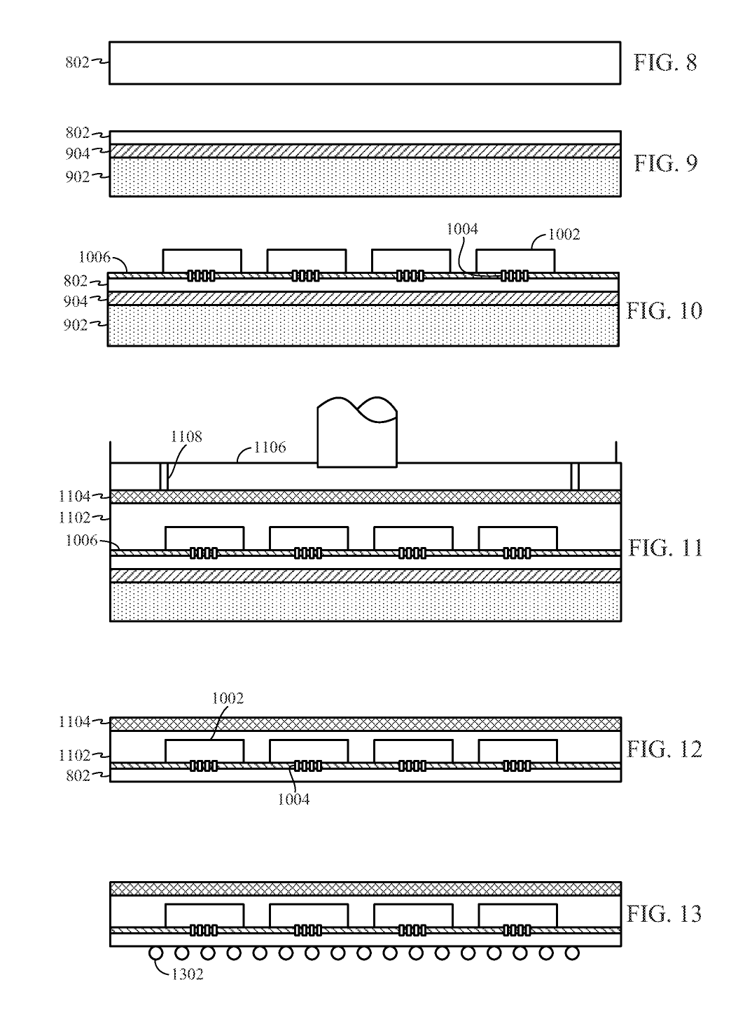

In FIG. 9 and block 704 of method 700, an adhesive material 904 can be applied to the frontside of the wafer 802. The wafer 802 can then be mounted to a carrier 902, such as tape, for further assembly processing. The carrier 902 provides stiffness and rigidity to the wafer 802 during the assembly process. As described above, this is important when the wafer undergoes a thinning process. When a thin wafer, e.g., a wafer thickness of approximately 50 μm, is formed, the wafer 802 can bend and/or sustain structural damage due to material stresses from various assembly processes. Thus, the carrier 902 provides protection to the thin wafer 202 during the assembly process.

Other assembly processes can include u-bumping and backside processing. In block 706 of method 700 and FIG. 10, for example, a die 1002 is coupled to the wafer 802. Also, an optional underfill layer 1006 can be disposed between the die 1002 and wafer 802 to enhance the reliability of the package. A plurality of u-bumps 1004 couple the die 1002 to the wafer 802. The die 1002 can be referred to as a Tier 2 die. As shown, there can be a plurality of Tier 2 dies 1002 coupled to the wafer 802 by the plurality of bumps 1004. And, although not shown, additional dies can be stacked to achieve a desired package.

Referring to block 708 of method 700, a wafer-level molding process similar to that described above in block 108 is completed. A mold compound 1102, which can be an epoxy-based material, for example, is applied to the wafer 802 such that the plurality of dies 1002 is surrounded by the mold compound 1102. The mold compound 1102 can provide stability to the thin wafer 802, but it is unable to provide sufficient stiffness required to prevent or significantly reduce warpage. As described above, applying a thicker layer of mold compound 1102 is undesirable because it increases the overall height of the package and can be expensive. Thus, the mold compound 1102 is applied to a desired thickness such that the mold compound 1102 surrounds the plurality of dies 1002 and covers the backside of the wafer 802.

The mold compound 1102 can be applied in several ways. In one embodiment, the mold compound 1102 can be dispensed onto the backside of the wafer 802, spun in a desired motion to spread the mold compound 1102 evenly, and then compressed. In the embodiment of block 710 and FIG. 11, the mold compound 1102 is liquid-based and compressed using a piston 1106. Once the mold compound 1102 is compressed to a desired thickness, it is cured at a curing temperature. The curing temperature can be between 150-250° C., for example. Depending on the type of mold compound 1102, the curing temperature may vary.

In this embodiment, before the mold compound 1102 cures a reinforcing material 1104 can be applied to the mold compound 1102. In block 712, a thin reinforcing material 1104 is disposed on the backside of the mold compound 1102. The reinforcing material 1104 can be glass, for example, or any other material that has similar mechanical and thermal properties as the wafer 802. Since glass and silicon have similar mechanical and thermal properties such as stiffness and coefficient of thermal expansion (CTE), the two materials can advantageously balance or reduce stresses and warpage during assembly and use. In addition, it is desirable for the reinforcing material 1104 to have a small thickness so that the overall package height is minimal.

In another embodiment, the reinforcing material 1104 can be prefabricated, applied to the mold compound 1102, and then the mold compound 1102 is cured. In this embodiment, the prefabricated reinforcing material 1104 can be used for compressing the mold compound 1102. For example, once the mold compound 1102 is applied to the backside of the wafer 802, the prefabricated reinforcing material 1104 can compress the mold compound 1102 to its desired thickness. In this example, once the mold compound 1102 is compressed, it cures at the curing temperature in block 714 of method 700.

The prefabricated reinforcing material 1104 can be used solely or in combination with the piston 1106 for compressing the mold compound 1102. When used in combination, a vacuum can be created through channels 1108 (FIG. 11) defined in the piston 1106 for coupling the reinforcing material 1104 to the piston 1106. As described above, the combined reinforcing material 1104 and piston 1106 can apply a uniform amount of pressure to the mold compound 1102 to achieve a desired mold compound thickness. In addition, the piston 1106 provides support to the thin reinforcing material 1104 during the compression process.

Once the mold compound 1102 is compressed to the desired thickness, the mold compound 1102 couples to the reinforcing material 1104 and the vacuum pressure is released. The piston 1106 can be removed from the reinforcing material 1104 and the assembly is cured in block 714.

In block 712, the coupling of the mold compound 1102 and reinforcing material 1104 can be aided or promoted by a surface roughening process. The surface of the reinforcing material 1104, for example, can be roughened before coupling the mold compound 1102 and reinforcing material 1104. There are several roughening processes or techniques that can be used. For example, the roughening process can be achieved by a dry or wet etching process. Plasma bombardment or etching is one form of a dry etching process that can be used.

In block 716 of the method 700 and FIG. 12, the carrier 902 is removed from the wafer 802. Before the wafer 802 is diced, flip-chip bumps 1302 can be fabricated on the frontside of the wafer 802 in block 718. As shown in FIG. 13, the bumps 1302 can be fabricated as flip chip bumps such that the package can be attached to a chip or substrate after the wafer 802 is diced.

In the embodiment of FIG. 7, the frontside bumping process in block 718 is completed after the carrier 902 is removed from the wafer 802. This is the primary distinction between the first embodiment described in method 100 and the second embodiment described in method 700. The second method 700 can be advantageous over the first method 100 because there is an increase in the margin for carrier/adhesive performance. The improved margin is related to the topography or surface flatness of the wafer.

In the first embodiment (e.g., method 100), the frontside bumps 306 can increase the surface height of the wafer 202 by 80-90 μm. This difference in surface height, or irregular surface flatness, can make it difficult to apply a substantially equal amount of adhesive along the surface of the wafer. In addition, if there are pockets or gaps along the wafer where there is an unequal amount of adhesive, it can be difficult to mount the carrier 302 to the wafer 202. More particularly, when the carrier 302 is not effectively mounted to the wafer 202, the carrier 302 provides less stiffness to the wafer 202. Thus, the wafer 202 can bend, warp, or suffer other structural damage. To overcome this variation in surface height, the wafer 202 may require a stricter manufacturing process that includes tighter tolerances. For instance, in some embodiments, the surface variation of the wafer may not exceed 5 μm and this can be difficult to manufacture.

Conversely, in the second embodiment, the frontside bumping process is completed near the end of method 700. In this instance, the adhesive material 904 can be applied more effectively to the surface of the wafer 802. More importantly, the carrier 902 can more effectively be mounted to the wafer 802. This improves the performance of the carrier 902 and provides a more desirable stiffness to the wafer 802 during the assembly process.

In addition, in the second embodiment, the wafer 802 can have a larger variation in surface height. For example, the wafer 802 can have a surface variation between 5-10 μm that does not require as stringent of a manufacturing process as in the first embodiment. The tolerances are not as strict and this can reduce the cost of manufacturing the wafer 802. Also, because the carrier 902 is able to mount more easily to the wafer 802 in this embodiment, it is also able to demount from the wafer 802 more easily.

Although there is at least one distinction between the embodiments described in methods 100 and 700, both methods can substantially reduce the warpage of the electronic package. In one non-limiting example, a study was performed on an electronic package similarly configured as the two embodiments shown in FIGS. 6 and 13. In this non-limiting example, warpage was measured on the bottom surface of the Tier 1 die (or wafer) after the carrier was demounted from the wafer. In the study, the thickness of the reinforcing material varied between 0-400 μm and the thickness of the mold compound varied between 100-400 μm. The Tier 2 die had a thickness of approximately 100 μm and the wafer or Tier 1 die had a thickness of approximately 50 μm. The mold compound and reinforcing material were cured at about 175° C. and 220° C., respectively.

In this non-limiting example, the warpage was reduced by 50-90% over conventional methods known in the art. The greatest reduction of warpage was measured when the thickness of the reinforcing material was similar to the thickness of the Tier 1 die. Regardless, however, of the different thicknesses of each material, the warpage was significantly reduced when the electronic package included the mold compound disposed between the wafer and the reinforcing material. When the electronic package was assembled without a reinforcing material, a substantial amount of warpage was measured. Thus, the reinforcing material can provide significant reduction to warpage over conventional electronic packages.

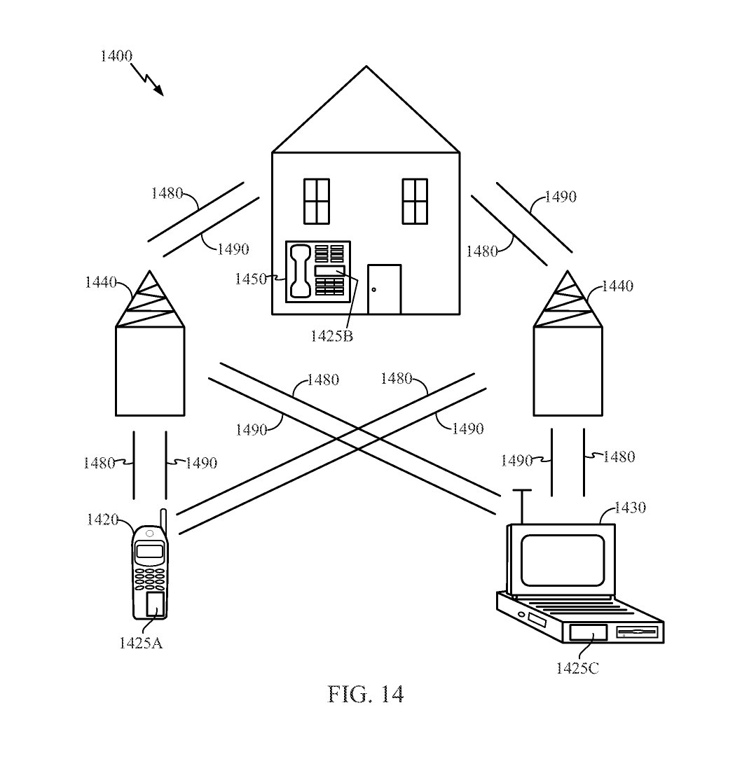

FIG. 14 shows an exemplary wireless communication system 1400 in which an embodiment of an electronic package with a reinforcing layer may be advantageously employed. For purposes of illustration, FIG. 14 shows three remote units 1420, 1430, and 1450 and two base stations 1440. It should be recognized that typical wireless communication systems may have many more remote units and base stations. Any of remote units 1420, 1430, and 1450, as well as the base stations 1440, may include an electronic package with a reinforcing layer such as disclosed herein. FIG. 14 shows forward link signals 1480 from the base stations 1440 and the remote units 1420, 1430, and 1450 and reverse link signals 1490 from the remote units 1420, 1430, and 1450 to base stations 1440.

In FIG. 14, remote unit 1420 is shown as a mobile telephone, remote unit 1430 is shown as a portable computer, and remote unit 1450 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 14 illustrates certain exemplary remote units that may include an electronic package with a reinforcing layer as disclosed herein, the package is not limited to these exemplary illustrated units. Embodiments may be suitably employed in any electronic device in which an electronic package with a reinforcing layer is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for forming an electronic package, comprising:
providing a wafer;
coupling a die to the wafer;
applying a mold compound material to the wafer, the mold compound material surrounding the die;
applying a reinforcing material to the mold compound material, wherein the mold compound material is disposed between the wafer and the reinforcing material.

2. The method of claim 1, wherein the reinforcing material is glass and the wafer is silicon.

3. The method of claim 1, wherein the reinforcing material includes mechanical properties similar to the wafer.

4. The method of claim 1, wherein the die is coupled to the wafer before applying the mold compound material.

5. The method of claim 1, further comprising mounting the wafer to a carrier.

6. The method of claim 5, further comprising applying frontside bumping before mounting the wafer.

7. The method of claim 5, further comprising removing the wafer from the carrier.

8. The method of claim 7, wherein the wafer is removed from the carrier after applying the reinforcing material.

9. The method of claim 5, further comprising applying frontside bumping after the wafer is removed.

10. The method of claim 1, further comprising roughening a portion of the reinforcing material before applying the reinforcing material.

11. The method of claim 1, wherein the thickness of the reinforcing material is approximately between the thickness of the wafer and the combined thickness of the wafer, the die, and the mold compound material.

12. The method of claim 1, wherein the reinforcing material is prefabricated and then applied to the mold compound material.

13. The method of claim 1, wherein the reinforcing material is applied to the mold compound material and then cured.

14. The method of claim 1, further comprising using a piston to apply the reinforcing material to the mold compound material.

15. The method of claim 1, further comprising using a vacuum to apply the reinforcing material to the mold compound material.

16. The method of claim 1, wherein the die comprises a plurality of die.

17. The method of claim 1 incorporated into a device selected from a group consisting of a music player, a video player, an entertainment unit, a navigation device, a communications device, a personal digital assistant (PDA), a fixed location data unit, and a computer.

18. An electronic package, comprising:
at least one semiconductor die;
a mold compound material for supporting the die, wherein the mold compound material substantially surrounds the die; and
a reinforcing material having similar mechanical properties to the semiconductor die, wherein the mold compound material is disposed between the die and the reinforcing material.

19. The package of claim 18, wherein the reinforcing material is glass and at least one of the semiconductor die is silicon.

20. The package of claim 18, wherein at least a portion of the reinforcing material has a roughened surface.

21. The package of claim 20, wherein the roughened surface is disposed in contact with the mold compound material.

22. The package of claim 20, wherein the thickness of the reinforcing material is approximately between the thickness of the mold compound material and the thickness of the semiconductor die.

23. The package of claim 22, further comprising flip chip bumping on the front side of the semiconductor die.

24. The package of claim 18 incorporated into a device selected from a group consisting of a music player, a video player, an entertainment unit, a navigation device, a communications device, a personal digital assistant (PDA), a fixed location data unit, and a computer.

25. An electronic package assembly, comprising:
a stack of semiconductor die;
a means for reducing warpage in the assembly, the means for reducing having similar mechanical properties as the stack; and
a means for supporting the stack;
wherein, the means for supporting surrounds the stack and is disposed between the stack and the means for reducing.

26. The assembly of claim 25, wherein the means for reducing is glass.

27. The assembly of claim 25, wherein at least a portion of one side of the means for reducing has a roughened surface.

28. The package of claim 27, wherein the roughened surface is in contact with the means for supporting.

29. The package of claim 25, wherein the means for supporting comprises an epoxy-based or silicon-based material.

30. The package of claim 25, further comprising flip chip bumping on the front side of the stack of semiconductor die.

31. The package of claim 25 incorporated into a device selected from a group consisting of a music player, a video player, an entertainment unit, a navigation device, a communications device, a personal digital assistant (PDA), a fixed location data unit, and a computer.

32. A method of fabricating a reinforced electronic package, comprising:
providing at least one semiconductor die and a reinforcing material;
applying a mold compound material to the die, wherein the mold compound material surrounds a portion of the die; and
step for reducing warpage in the package;
wherein, the mold compound material is disposed between the semiconductor die and reinforcing material.

33. The method of claim 32, further comprising mounting the semiconductor die to a carrier.

34. The method of claim 33, further comprising removing the semiconductor die from the carrier.

35. The method of claim 34, further comprising applying frontside bumping after the semiconductor die is removed.

36. The method of claim 34, wherein the semiconductor die is removed from the carrier after the step for reducing warpage.

37. The method of claim 33, further comprising applying frontside bumping before mounting the semiconductor die.

38. The method of claim 32, further comprising roughening a portion of the reinforcing material.

39. The method of claim 32, wherein the step for reducing includes applying a reinforcing material to the mold compound material.

40. The method of claim 32 incorporated into a device selected from a group consisting of a music player, a video player, an entertainment unit, a navigation device, a communications device, a personal digital assistant (PDA), a fixed location data unit, and a computer.
